(19) United States
(12) Patent Application Publication
(10) Pub. No.: US 2007/0079870 A1
(43) Pub. Date: Apr. 12, 2007

(54) Photoelectrochemical cell with bipolar dye-sensitized electrodes for electron transfer

(75) Inventors: Jong Hyeok Park, Austin, TX (US); Allen J. Bard, Austin, TX (US)

Correspondence Address: CHALKER FLORES, LLP, 2711 LBJ FRWY, Suite 1036, DALLAS, TX, 75234, US

(73) Assignee: Board Of Regents, The University Of Texas System, Austin, TX (US)

(21) Appl. No.: 11/546,591

(22) Filed: Oct. 12, 2006

Related U.S. Application Data
(60) Provisional application No. 60/726,037, filed on Oct. 12, 2005.

(51) Int. Cl. H01L 31/00

(52) U.S. Cl. 136/263

(57) ABSTRACT

The present invention is a monolithic photoelectrochemical cell for photoelectrical-induction of a chemical reaction and a method capable of vectorial electron transfer apparatus including one or more semiconductor electrodes and one or more dye sensitized electrodes positioned in communication with an electrolyte whereby the electrode is capable of vectorial electron transfer upon exposure to electromagnetic radiation.

### CROSS-REFERENCE TO RELATED APPLICATIONS

This application claims priority to U.S. Provisional Application Ser. No. 60/726,037, filed Oct. 12, 2005, the contents of which is incorporated by reference herein in its entirety.

The present invention was made with U.S. Government support under Contract No. CHE 0202136 awarded by the National Science Foundation, and as such, the government has certain rights in this invention.

### TECHNICAL FIELD OF THE INVENTION

The present invention relates in general to the field of photoelectrolysis, and more particularly, to the photoelectrolysis of water with a multielectrode semiconductor photoelectrochemical cell capable of unassisted photolytic water splitting.

### BACKGROUND OF THE INVENTION

Without limiting the scope of the invention, its background is described in connection with photolytically-induced decompositions, as an example.

The limited supply of fossil fuels and the problems associated with the combustion of those fuels have been an increasing concern for the countries of the world. As a result much attention has been turned to alternative sources of energy, e.g., solar, nuclear and wind. One potential source of energy is the use of solar cells to convert radiant energy into electrical energy thereby providing a renewable source of clean energy.

Generally, solar cells are divided into two types. One is a silicon solar cell, while the other one is a compound semiconductor solar cell. The silicon solar cell includes a crystallized solar cell such as a single crystalline silicon solar cell and a poly-crystalline silicon solar cell, which has a thinner semiconductor layer, a higher light absorption coefficient, and a lower manufacturing cost.

The compound semiconductor solar cell can also be used to convert solar radiation to electrical energy using solar cells as well as carrying out photolytically-induced decompositions such as the photolysis of water into H₂ and O₂ using light from, for example, solar radiation.

Photolytically induced decompositions, particularly the photolysis of water into H₂ and O₂ using solar radiation, have received extensive attention and various photoelectrochemical devices and photolysis methods been developed. One method of water photoelectrolysis uses TiO₂ and Pt electrodes; however, the potential developed by the TiO₂ is inadequate to drive the reaction at a useful rate. An external bias must be applied by either an external electrical potential or a chemical bias (e.g., contacting the TiO₂ with a strong alkaline and the Pt with a strong acidic solution) to establish a useful reaction rate. Even when several photoactive junctions are connected in series to produce sufficient driving force water photoelectrolysis without an external bias, the practically of the device is limited by problems associated with the complicated construction of the device and difficulties in the separation and collection of H₂ and O₂, thus impeding practical application.

Another method currently used in the art, includes the dye-sensitized solar cells (DSSC) developed by Dr. Michael Gratzel and coworkers at the Swiss Federal Institute of Technology. Generally, DSSC uses a network of liquid electrolyte and dye-coated sintered titanium dioxide to produce a multielectrode photoelectrochemical cell for a photoelectrochemical reactions. Conventionally, fabrication of DSSCs often requires a high temperature sintering process to achieve sufficient interconnectivity between the nanoparticles and enhanced adhesion between the nanoparticles and a transparent substrate. Additionally, the high temperature sintering technique used to make these cells limits the cell substrate to rigid transparent materials (e.g., glass) and consequently limits the manufacturing to batch processes and the applications to those tolerant of the rigid structure. The liquid electrolytes within the cell are prone to leakage, which creates not only environmental issues, but also long-term stability issues.

In a typical DSSC, an inexpensive, nanocrystalline semiconductor material, such as TiO₂, is sintered onto a conductive glass substrate. While the large band gap of most metal oxides prevents direct absorption of sunlight, sensitization by a variety of inorganic and organic dyes provides very efficient charge injection into the semiconductor. The high surface area of the TiO₂ allows a monolayer of dye molecules to absorb almost all incident light above the absorption threshold energy of the dye. The excited state of the dye then injects an electron into the conduction band of the TiO₂. Donation of an electron from a mobile redox species in the electrolyte solution subsequently regenerates the oxidized dye. The injected electron percolates to the back contact, where it produces a current through an external load. The electron then returns to the cell through a metallized counter electrode, where it reduces the hole carrier in the electrolyte solution, completing the circuit. Conventional systems that use DSSC can convert solar radiation into electrical energy at about 10% efficiency.

### SUMMARY OF THE INVENTION

The present inventors recognized a need for photoelectrochemical device for photolytically-induced decompositions such as the photolysis of water to convert solar energy to electrical power, while providing as system that does not requiring an external bias.

The present inventors recognized that the key requirement in cells that can make H₂ and O₂ simultaneously with a single semiconductor electrode is the discovery of a semiconductor material that remains stable under irradiation with an appropriate band gap (>about 2.5 eV) and with a conduction band sufficiently negative for hydrogen evolution and the valence band sufficiently positive for oxygen evolution. The most suitable semiconductors in aqueous solution are oxides, including TiO₂, WO₃, ZnO and SrTiO₃, but the band gaps of these are so large that the solar efficiency of such cells is very small. Recently, photochemical water splitting by chemically modified n-TiO₂ was described, but the energetics was not suitable for water splitting and required an additional external electrical bias.

To overcome the problems of a large band gap and inefficient utilization of the solar spectrum with TiO₂ the present inventors recognized that dye-sensitizers can be adsorbed on the surface of the electrode or particle. However, a fundamental problem with dye-sensitized systems for oxygen evolution is the photochemical instability of the sensitizer under conditions when holes sufficiently energetic to liberate oxygen from water are produced upon irradiation. Approaches using dye-sensitized solar cells with the iodide/iodine electrolyte for the direct cleavage of water into H₂ and O₂ have been reported; however that was based on the external series connection of two different photosystems. The present inventors recognized the primary disadvantages were the need for external wiring and the stability problem of the semiconductor contacting the water.

During the last decade, a 10.4% light-to-electricity conversion efficiency at air mass 1.5 solar irradiance has been obtained for photovoltaic devices with a panchromatic dye coating nanoporous TiO₂ and a nonaqueous electrolyte containing the iodide/iodine couple in a dye-sensitized solar cell (DSSC). A series array of bipolar TiO₂/Pt and CdSe/CoS photoelectrodes capable of vectorial electron transfer have permitted water splitting to H₂ and O₂ without an additional input of energy. The present invention provides dye-sensitized solar cells by constructing novel bipolar electrodes, using the iodide/iodine couple in MeCN for internal connections. The present invention overcomes difficulties that are frequently encountered in photoelectrochemical cells: the energetic issue for the reaction and the instability of the semiconductor photoelectrode under conditions where the reaction of interest occurs.

The present invention relates to photolytically-induced decompositions such as water photoelectrolysis, particularly with a multielectrode semiconductor photoelectrochemical cell capable of unassisted photolytic water splitting to form H₂ and O₂ and methods of making and using same. The present invention does not require that the semiconductor have a flatband potential more negative than the reduction potential of H₂O or that the semiconductor be stable with respect to photo-oxidation while evolving oxygen.

The photoelectrically-induced reaction of most general interest is the decomposition of water to hydrogen and oxygen, however many other photodriven reactions (e.g. that of brine to produce hydrogen, chlorine, and alkali) can be carried out. In one aspect the multielectrode photoelectrochemical unit comprises a wireless series of at least two photoactive bipolar electrode panels. The multielectrode photoelectrochemical unit characteristically comprises a housing and at least two photoactive bipolar electrode panels and may also include a means for collecting evolved gaseous photodecomposition products. The housing has at least one light-passing side, a first end, a second end and a housing wall defining an internal section. The term “light-passing” as used herein indicates light-transparent or light-translucent, so that substantially all incident light may pass on into the housing interior.

The present invention provides a wide band gap semiconductor of nanocrystalline, mesoporous material covered with a dye. Generally, the semiconductor material is deposited onto a transparent conductive oxide electrode and covered with a monolayer of dye molecules. The pores of the semiconductor material are filled with a redox electrolyte, which functions as a conductor. For example, the nanocrystalline; mesoporous semiconductor material TiO₂ is deposited onto a transparent conductive oxide electrode and covered with a monolayer of dye molecules. The pores of the semiconductor material are filled with an I⁻/I₃⁻ electrolyte solution. The cell is then illuminated and the electrons from the dye molecules are transferred to the semiconductor and move toward the transparent conductive oxide electrode substrate. The electrolyte reduces the oxidized dye and transports the positive charges as I₃⁻ to the electrode.

The present invention includes a monolithic photoelectrochemical cell for photoelectrical-induction of a chemical reaction capable of vectorial electron transfer. The monolithic photoelectrochemical cell includes one or more semiconductor electrodes and one or more dye sensitized electrodes positioned in communication with an electrolyte whereby the electrodes are capable of capable of vectorial electron transfer upon exposure to electromagnetic radiation.

For example, the present invention includes a monolithic photoelectrochemical cell for photoelectrical-induction of a chemical reaction capable of vectorial electron transfer including a WO₃ semiconductor electrode and a ruthenium sensitized TiO₂ electrode positioned in communication with an iodide/iodine electrolyte whereby the electrode is capable of capable of vectorial electron transfer upon exposure to electromagnetic radiation.

More particularly, the present invention includes an inducible photoelectrochemical cell for photoelectrical-induction of a chemical reaction. The cell includes a housing having a first end and a second end connected by one or more walls with one or more semiconductor electrodes and one or more dye sensitized electrodes positioned within the housing. The one or more semiconductor electrodes and the one or more dye sensitized electrodes are in communication through an electrolyte.

The present invention provides a method of making an inducible photoelectrochemical cell by forming one-or more semiconductor electrodes, forming one or more dye sensitized electrodes positioned and the connecting of the one or more semiconductor electrodes and the one or more dye sensitized electrodes with an electrolyte.

For example, the present invention includes a method of producing electrical energy using an inducible photoelectrochemical cell by forming one or more semiconductor electrodes, forming one or more dye sensitized electrodes and the connecting of the one or more semiconductor electrodes and the one or more dye sensitized electrodes with an electrolyte. The method provides for the exciting the one or more semiconductor electrodes, the one or more dye sensitized electrodes or combination thereof. Additionally, the present invention includes a housing having a first end and a second end connected by one or more walls with one or more semiconductor electrodes and one or more dye sensitized electrodes positioned within the housing.

The present invention includes a method of making a monolithic photoelectrochemical cell by forming one or more semiconductor electrodes, forming one or more dye sensitized electrodes and the connecting of the one or more semiconductor electrodes and the one or more dye sensitized electrodes with an electrolyte.

The present invention also includes a method of using solar energy using a monolithic photoelectrochemical cell by forming one or more semiconductor electrodes, forming one or more dye sensitized electrodes and connecting of the semiconductor electrode and the dye sensitized electrode with an electrolyte. The method provides for the exciting the one or more semiconductor electrodes, the one or more dye sensitized electrodes or combination thereof. Additionally, the present invention includes a housing having a first end and a second end connected by one or more walls with one or more semiconductor electrodes and one or more dye sensitized electrodes positioned within the housing.

### BRIEF DESCRIPTION OF THE DRAWINGS

For a more complete understanding of the features and advantages of the present invention, reference is now made to the detailed description of the invention along with the accompanying figures and in which:

FIGS. 1a and 1b are schematics of one embodiment of the water photoelectrolysis cell of the present invention;

FIG. 2 is an illustration of the energy level for the photoelectrochemical water splitting device;

FIG. 3a is a plot of the photocurrent verses potential for WO₃ electrodes illuminated with a xenon lamp;

FIG. 3b is a plot of the photocurrent behavior of inner DSSC as a function of light intensity;

FIG. 4a is a plot of the current density verses voltage characteristics for PEC tandem cells;

FIG. 4b is a plot of the solar-to-hydrogen conversion efficiency as a function of applied potential;

FIG. 5 is a plot of the photocurrent verses potential for WO₃ electrodes illuminated with a xenon lamp;

FIGS. 6a, 6b and 6c are schematics of another embodiment of the water photoelectrolysis cell of the present invention;

FIG. 7 is an illustration of the energy-level for water splitting with the bipolar photoelectrode array;

FIG. 8 is a graph that displays-the power characteristics of a three photoelectrode array;

FIG. 9 is a schematic of another embodiment of the water photoelectrolysis cell of the present invention;

FIG. 10a is a graph of the current density-voltage characteristics for photoelectrode PEC array under white light illumination;

FIG. 10b is a graph of the photocurrent time profile at short circuit for internal photovoltaic cells;

FIG. 11 is a graph of the photocurrent-voltage curves the inner photovoltaic cells as a function of photoelectrode connection numbers;

FIG. 12 is a graph of the photocurrent-voltage curves for a photoelectrode PEC array under white light illumination; and

FIG. 13 is a graph of the production of hydrogen and oxygen in a photoelectrode PEC array.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The terminology used and specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

Direct splitting of water into hydrogen and oxygen by solar light in photoelectrochemical cells (PECs) has received much attention, since hydrogen is often considered the energy storage medium of the next generation.^{i,ii,iii} Various photoelectrochemical approaches have been introduced for evolving hydrogen directly from sun-light and water, and offer the possibility of increasing the efficiency of the solar-to-hydrogen pathway.^{iv,v} Although tandem cells based on III/V semiconductors have achieve high efficiencies, in the range of about 12˜20%, these single-crystals materials are too expensive for large-area terrestrial applications.^{vi} Therefore, the main target in recent studies on solar energy conversion is to reduce the fabrication cost while maintaining a reasonable conversion efficiency.

Various inexpensive approaches by using semiconductor/electrolyte junctions have been proposed, since the pioneering work by Fujishima and Honda^{vii}, but solar the conversion efficiency reported still remains quite low (less than about 1%). Recently, Yamada and coworkers demonstrated a device that integrates an amorphous silicon triple-junctioh solar cell coated with thin film catalysts for the hydrogen and oxygen evolution reaction operating at about 2.5% efficiency.^{viii} More recently a new hybrid silicon/photoelectrochemical multijunction cell with about 2.2% efficiency was reported.^{ix} However, the structure of the silicon based tandem cell with a multilayer p-i-n junction is complicated. Gratzel has described a low-cost tandem device, based on two photosystems (e.g., WO₃ and dye-sensitized solar cell) connected in series that achieved direct water splitting into hydrogen and oxygen by UV-visible light.^{x} The primary disadvantage of this system is the need for external wiring to connect the WO₃ film electrode to a separate dye-sensitized solar cell (DSSC) based on nanoparticulate TiO₂. Nevertheless, the tandem cell scheme using nanocrystalline WO₃ and a DSSC is an interesting candidate for a low cost water splitting system.

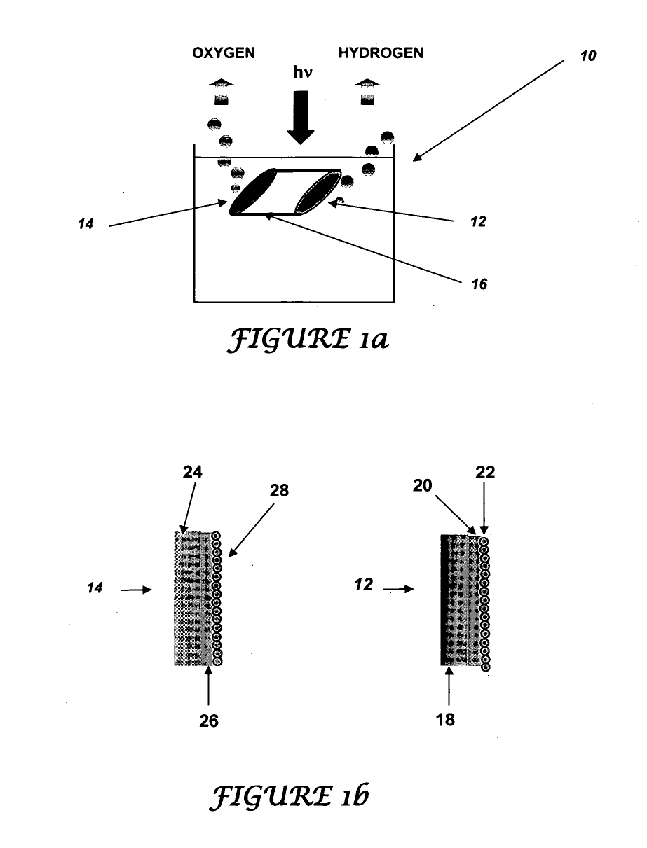

FIGS. 1a and 1b are schematics of one embodiment of a water photoelectrolysis cell of the present invention, where the expansion in FIG. 1b shows concrete structure and energetics of bipolar panel. The water splitting cell using bipolar WO₃/Pt and dye-sensitized TiO₂/Pt electrodes capable of vectorial electron transfer using two bipolar electrodes connected by the iodide/iodine couple in MeCN for the internal connections (e.g., MeCN+I₂+LiI⁺ t-butylpyridine) and can permit unassisted photolytic water splitting with oxygen evolved at the WO₃ semiconductor surface and hydrogen evolved on a platinum surface. The device of the present invention is different than previously reported tandem cells in the art (e.g., the Gratzel group) in that the external wiring between the photoelectrochemical cells has been replaced by internal vectorial electron transfer resulting in a monolithic water splitting device. The present invention also introduced photocatalytic behavior of the WO₃ photoanode to offer specificity in Cl₂ production. FIGS. 1a and 1b are schematics of a water photoelectrolysis cell 10 having a TiO₂/Pt electrodes 12 and a WO₃/Pt electrode 14 separated by an iodide/iodine couple in MeCN for the internal bridge 16. The TiO₂/Pt electrodes 12 has a dye sensitized TiO₂ layer 18 in contact with a Ti foil layer 20, which is in contact with a Pt film 22. The WO₃/Pt electrode 14 includes a WO₃ film 24 in contact with a Ti foil 28.

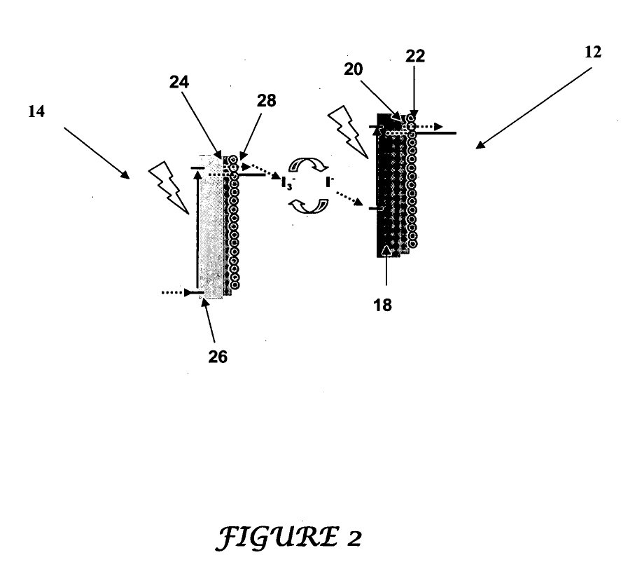

FIG. 2 illustrates the energy level diagram for the photoelectrochemical water splitting device, where the energetics of vectorial electron transfer from one bipolar photoelectrode to the other. The scheme consists of two photons required to produce one separated electron-hole pair. Since the photocurrent of tandem cells is limited by the lowest-current cell, current-matching in the component cells is critical for good performance. FIG. 2 is a schematic of the energy level diagram having a TiO₂/Pt electrode 12 and a WO₃/Pt electrode 14 separated by an iodide/iodine couple in MeCN for the internal bridge not shown. The TiO₂/Pt electrode 12 has a dye sensitized TiO₂ layer 18 in contact with a Ti foil layer 20, which is in contact with a Pt film 22. The WO₃/Pt electrode 14 includes a WO₃ film 24 in contact with a Ti foil 28. The reaction at the TiO₂/Pt electrodes 12 is H₂O→½H₂ while the reaction at the WO₃/Pt electrode 14 is H₂O→¼O₂.

The photocurrent density of the WO₃ film coated was optimized on a mechanically polished Ti substrate (e.g., about 0.25-mm-thick, by Aldrich) by photoelectrochemical studies of the electrode alone. Peroxotungstic acid sol (e.g., WO₃₋ₓ. nH₂O) was synthesized by dissolving tungsten powder (e.g., about 1g) in an ice-cooled beaker containing about 30% H₂O₂ aqueous solution (e.g., about 5 mL) and then diluting the solution with a water/2-propanol mixture (volume ratio of about 5:2).^{xi} The WO₃ was deposited on a mechanically polished Ti substrate by electrophoresis (about −430 mV vs. Ag/AgCl, Pt mesh counter) from this solution for 30 min and then annealed in air at about 450° C. for about 30 min. The thickness of WO₃ was controlled by consecutive electrodepositions, each followed by a heat treatment. The photoelectrochemical measurements were carried out in a three electrode system, by illuminating with about a 2500 W xenon lamp from which infrared wavelengths were removed by an 8-in water filter. The measured light irradiance was about 100 mW/cm². The potential of the WO₃ electrode was monitored versus an Ag/AgCl reference electrode in about 0.25 M Na₂SO₄ acidified to pH about 4.0 with perchloric acid.

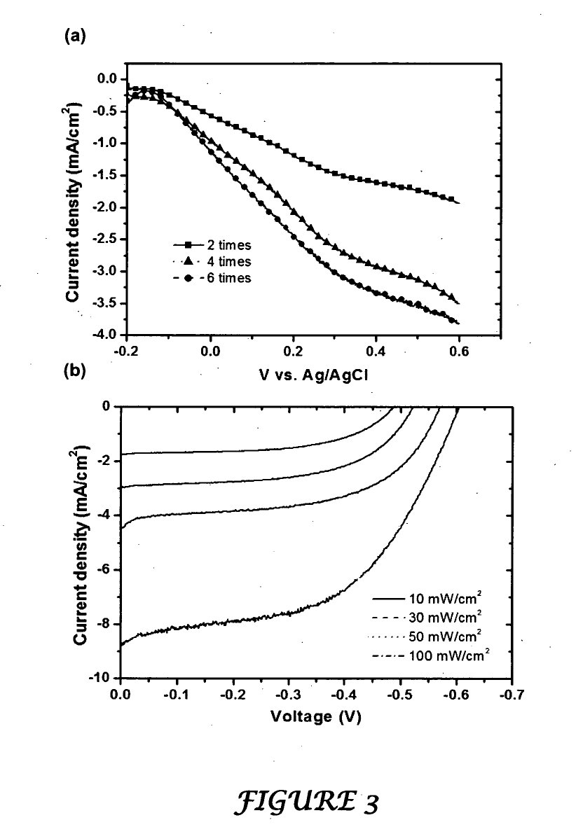

FIG. 3a is a plot of the photocurrent verses potential for WO₃ electrodes illuminated at 100 mW/cm² with a xenon lamp, solution, 0.2 M Na₂SO₄ (pH 4). FIG. 3a illustrates the photocurrents of the WO₃/Ti foil electrodes with different film thicknesses, controlled by the number of deposition steps. The dark current in the potential region about −0.2 to about 0.6 V was negligible. The photocurrent onset occurred at about −0.1 V. The onset shifted slightly negative with increasing light intensity. Each curve showed an increase in photocurrent until saturation was reached at about 0.6 V. Under illumination, the saturation photocurrent associated with the photogeneration of oxygen reached about 3.7 mA/cm².^{xii} There was no significant pH changes of the bulk electrolyte during the photoelectrochemical tests.

To characterize the photocurrent characteristics of the DSSC about a 15-nm-thick platinum film was deposited onto one side of about 0.25-mm-thick Ti foil (e.g., area of about 0.12 cm²) by sputtering. About a 15-μm-thick film of TiO₂ nanoparticles (e.g., Konarka Corp. Lowell, Mass.) was printed on another Ti foil. After sintering at about 450° C. for 30 minutes and cooling to about 80° C., the TiO₂ coated Ti foil was dye-coated by immersing it in about 0.3 mM solution of the Ru-dye Z-907 (e.g., Konarka) in acetonitrile and t-butanol (e.g., volume ratio 1:1) at room temperature for about 24 hours. Both the WO₃/Pt and DSSC/Pt electrodes were inserted into a Pyrex glass tube and attached with a curable epoxy (e.g., Devcon Co.) resin at about a 45° angle, with a spacing of about 1 cm, to allow irradiation of the photoactive sides of the electrodes. An iodide/iodine-containing electrolyte (e.g., 0.005 M I₂+0.5 M LiI+0.58 M t-butylpyridine in MeCN) filled the Pyrex tube to connect electrolytically the internal faces of the two bipolar electrodes.

FIG. 3b illustrates the photocurrent vs. voltage characteristics of the DSSC (e.g., Pt coated Ti foil/1cm-electrolyte/dye-sensitized TiO₂ coated Ti foil) measured at different incident light intensities. The fill factor (FF) of the device was about 0.5 at about 100 mW/cm². Moreover, the open circuit voltage, V_{OC}, and short circuit current density, i_{sc}, increased monotonically, reaching maximum values of V_{oc}=about 0.61 and i_{sc}=about 9 mA/cm², respectively.

The tandem cell requires two photons to produce one electron in the external circuit, great care must be taken in each cell to match the photocurrent. For water splitting, the photocurrent density was adjusted by controlling the areas of the WO₃ photoelectrode and the dye sensitized TiO₂ photoelectrode.

The ultimate aim of a solar energy storage system would be to photosynthesize an energy-rich chemical (e.g., H₂ from H₂O) without the application of any external bias voltage. As can be seen FIG. 3a, the system constructed with WO₃ as the photoanode has useful properties, although the wide band gap of this material (e.g., about 2.8 eV) precludes efficient utilization of the solar spectrum. To obtain solar-to-hydrogen conversion efficiency, the cell was placed in a water jacket as shown in FIG. 1a.

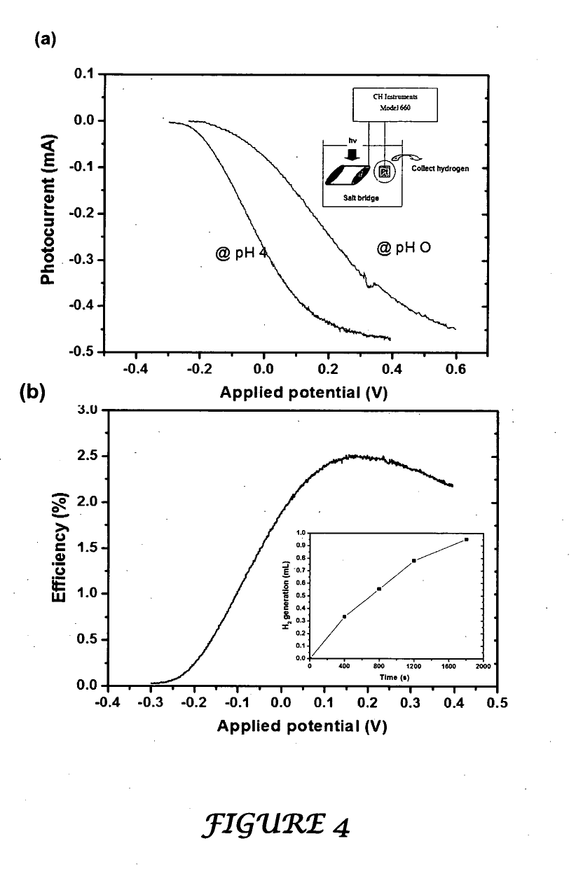

FIG. 4a illustrates the current density verses voltage characteristics for PEC tandem cells connected by either 1 M HClO₄ (pH 0) or 0.25 M Na₂SO₄₊HClO₄ (pH 4) under white light illumination (total area about 0.18 cm²). Inset shows schematic of the two-compartment electrochemical cell for measuring photocurrent of photoelectrolysis cell. FIG. 4b illustrates the solar-to-hydrogen conversion efficiency as a function of applied potential. Inset shows hydrogen production from the tandem cell at open circuit state under 200 mW/cm² and 0.25 M Na₂SO₄ (pH 4) electrolyte.

The inset of FIG. 4a illustrates the PEC and PV components of the device can be separated. In the two-electrode configuration, the working electrode is a tandem cell (the back face of 12 was coated with an insulating polymer layer and the working electrode lead was connected to 12) and the counter and reference electrode leads were connected to a Pt plate electrode. This displaces, for measurement purposes, the Pt cathode to one where the current could be monitored. Under illumination, electrons flow from WO₃ to the right of the tandem cell, oxidizing water and generating oxygen. Electrons flow to the DSSC and pass through the external circuit to the Pt plate electrode.

Although the tandem cell has the proper band gap for water splitting, its band edges should be adjusted to produce hydrogen and oxygen simultaneously. The band positions of water oxidation and reduction can be easily tuned by adjusting the electrolyte pH. For example, in water splitting different kinds of electrolytes with different pH can be used. FIG. 4a illustrates the bias voltage dependence of the photocurrent of the tandem cell under illumination. The tandem cell in pH 4 electrolyte started to generate hydrogen at a voltage about 0.2 V negative of 0 V bias, indicating that no additional external voltage was needed for this tandem cell to split water. The light-limiting current was reached at a positive bias (about 0.3 V) and remained almost constant with increasing bias. The zero bias point represents the maximum short-circuit photocurrent for water splitting and is the operating point for the cell in photoelectrolysis mode. The current is a result of a combination of the voltage the cell is generating and the voltage needed for water splitting at that photocurrent density.^{xiii} FIG. 4a is a graph that illustrates the photocurrent of the cell of the present invention with the plateau at about 0.2 V past the zero bias point. The tandem cell operating at pH 0 started to generate hydrogen at about 0 V bias and reached saturated photocurrent at about 0.6 V, indicating that additional external voltage was needed for efficient water splitting under these conditions. The better performance at pH 4 compared to pH 0 suggests that improving the kinetics of water oxidation at WO₃ is more important than that of H₂ evolution at Pt. In addition, alkaline electrolytes may also be used with the present invention; however, the WO₃ is not stable under illumination at pH's above 5.

The chemical efficiency during hydrogen production was calculated with the following equation:
efficiency=(power out)/(power in).
The input power is the incident light intensity of about 100 mW/cm². For the output power, assuming 100% photocurrent electrolysis efficiency, the hydrogen production photocurrent of about 0.28 mA/(e.g., total exposed cell area of about 0.18 cm²) at zero bias is multiplied by about 1.23 V, which is the ideal fuel cell limit at about 25° C. Using this equation, the hydrogen production efficiency of our system at zero bias was about 1.9%.

FIG. 4b illustrates the hydrogen conversion efficiency as a function of potential. The maximum conversion efficiency was about 2.5% and observed around 0.2 V positive bias. FIG. 4b shows a quantitative description of the hydrogen evolution under zero bias as a function of time. A larger glass tube, with about a 1 cm² area larger and photoelectrodes were used. During about 1800 seconds of exposure to about 200 mW/cm2 xenon lamp illumination, about 1 mL of hydrogen gas was generated.

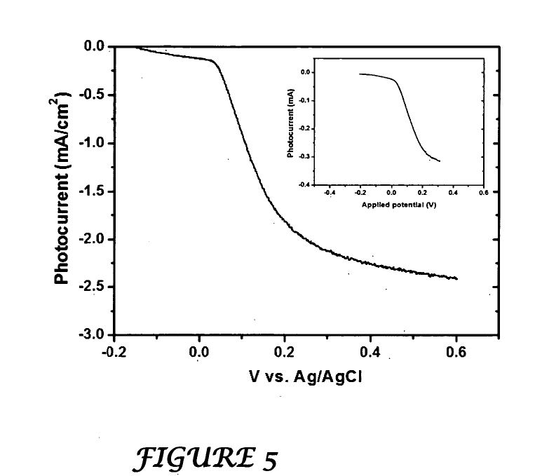

FIG. 5 illustrates a current-voltage curve for WO₃ photoanodes with about a 2 nm Pt catalyst in contact with about 15 M LiCl electrolyte (pH about 4). The potential to oxidize Cl⁻ is about 0.36 V higher than that for water oxidation at this pH, however the heterogeneous electron transfer rate for Cl⁻ oxidation is more favorable. To provide an even greater kinetic advantage for oxidation of Cl⁻, an electrolyte with high concentration of Cl⁻ was used. The onset potential was similar to O₂ evolution. However, a sharp increase in current density was observed at about 0.05 V. The Cl₂ gas was identified by its smell and by chemical analysis (e.g., oxidation of N,N-diethyl-p-phenylenediamine indicator by free chlorine). However, the WO₃ photoanode showed lower current density for Cl₂ evolution than for O₂ evolution. FIG. 5 illustrates the bias voltage dependence of the photocurrent of the tandem cell under illumination. Under small external bias, the tandem cell produces H₂ and Cl₂ simultaneously.

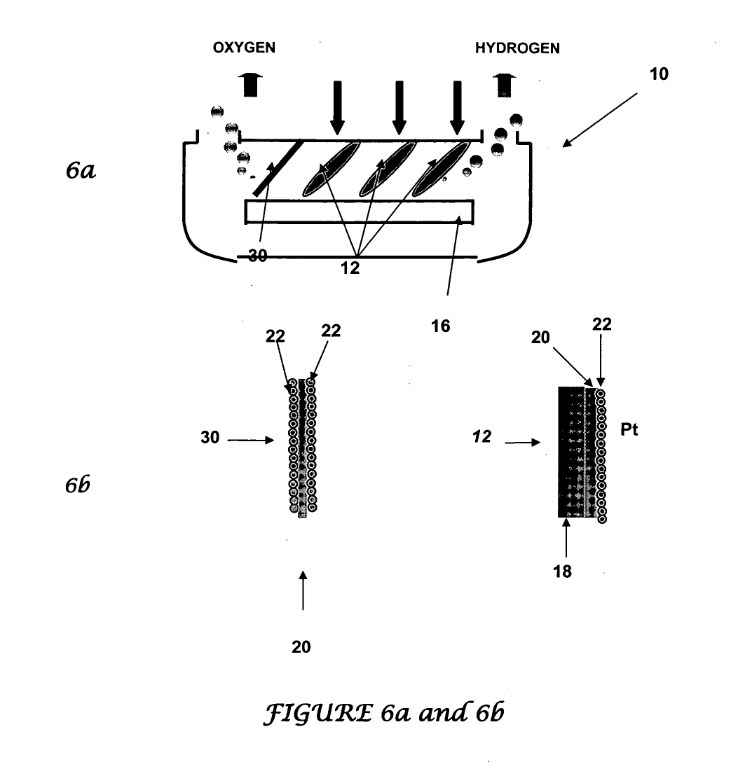

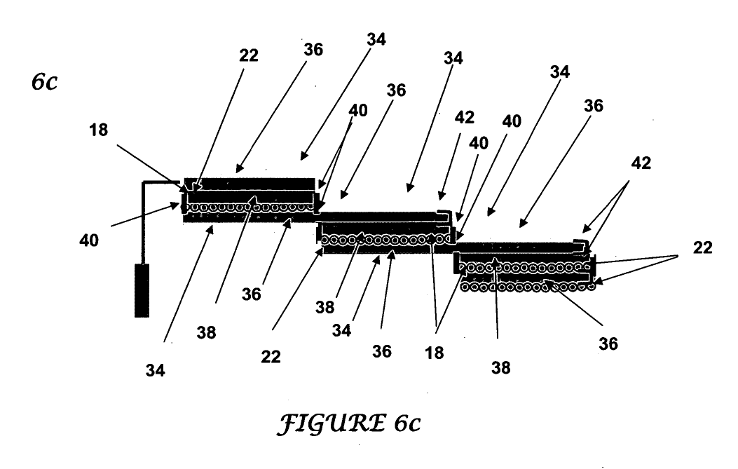

The present invention uses two different kinds of cells with bipolar dye-sensitized TiO₂/Pt panels connected so that their photovoltages add to provide vectorial electron transfer for unassisted water splitting to yield the separated products H₂ and O₂. Three internal cells [Pt/organic solvent with I⁻, I₂ electrolyte/dye coated TiO₂] behave as photovoltaic cells and the overall photovoltage provides the bias for driving the electrolysis of water at the outer Pt electrodes acting as the electrode and electrocatalysts for water oxidation to O₂ and reduction to H₂ as shown in FIG. 6. This arrangement overcomes additional difficulties that are frequently encountered in photoelectrochemical cells: the energetic issue for the reaction and the instability of the semiconductor photoelectrode under conditions where the reaction of interest occurs.

FIGS. 6a, 6b and 6c are schematics of another embodiment of the water photoelectrolysis cell 10 of the present invention, where FIGS. 6b and 6c show concrete structure and energetics of bipolar panel. The water splitting cell using bipolar Pt and dye-sensitized TiO₂/Pt electrodes capable of vectorial electron transfer using two bipolar electrodes connected by the iodide/iodine couple in MeCN for the internal connections (e.g., MeCN+I₂+LiI+t-butylpyridine) and can permit unassisted photolytic water splitting. The device of the present invention is different than previously reported tandem cells in the art (e.g., the Grätzel group) in that the external wiring between the photoelectrochemical cells has been replaced by internal vectorial electron transfer resulting in a monolithic water splitting device. FIG. 6 is a schematic of a water photoelectrolysis cell 10 having three TiO₂/Pt electrodes 12 and a Pt electrode 30 separated by an iodide/iodine couple in MeCN for the internal bridge 16. Each of the TiO₂/Pt electrodes 12 have a dye sensitized TiO₂ layer 18 in contact with a Ti foil layer 20, which is in contact with a Pt film 22. The Pt electrode 14 includes a Ti foil layer 20, which is in contact with a Pt film 22.

FIG. 6b is a schematic diagram of an embodiment of the present invention having Structure A. A 15-nm-thick platinum film was deposited onto one side of a 0.25-mm-thick Ti foil (e.g., area: 0.12 cm²) by sputtering and then about a 15-mm-thick film of TiO₂ nanoparticles (e.g., Konarka Technology Inc., (KTI), Lowell, Mass.) was printed on the back side. After sintering at about 450° C. for 30 min and cooling to 80° C., the TiO₂ coated Ti foil was dye-coated by immersing it in about a 0.3 mM solution of the Ru-dye Z-907 in acetonitrile and t-butanol (e.g., volume ratio 1:1) at room temperature for about 24 hours. The end (left) terminal electrode had Pt on both sides. The bipolar and Pt electrodes were inserted into a Pyrex glass tube and attached with a curable epoxy resin (e.g., Devcon Co.) at about a 45° angle, with spacing of about 1 cm, to allow irradiation of the photoactive sides of the electrodes. All dye coated TiO₂ regions in the array were in contact with an iodide/iodine electrolyte (e.g., 0.005 M I₂+0.5 M LiI+0.58 M t-butylpyridine in MeCN) and only the two terminal Pt electrodes contacted aqueous 2 M KOH, connected by a KOH salt bridge.

FIG. 6c is a schematic diagram of an embodiment of the present invention having Structure B: A schematic diagram of the structure is shown in FIG. 6c. The fluorine-doped SnO₂ conducting glass substrate (e.g., FTO glass, both sides coated) was obtained from Solaronix Co. (Aubonne, Switzerland) and cut into about 1 cm X about 1 cm pieces. The front and back sides were connected with a thin film of silver paste. One side of the FTO glass was first cleaned in Triton X-100 solution, then washed with ethanol, and finally treated with an aqueous solution of about 50 mM TiCl₄ at about 70° C. for about 30 min to make a good mechanical contact between conducting FTO glass and the TiO₂ layer that would be printed on it. A 15-nm-thick platinum film was deposited onto half of the untreated side of the FTO glass by sputtering and then about a 15-mm-thick film of TiO₂ nanoparticles was printed on half of the backside. After sintering at about 450° C. for about 30 min and cooling to about 80° C., the TiO₂ coated conducting FTO glass was dye-coated by immersing it into a 0.3 mM solution of the Ru-dye Z-907 in acetonitrile and t-butanol (e.g., volume ratio 1:1) at room temperature for about 24 h. The bottom terminal electrode located on the right in FIG. 6c had Pt on both sides, but only one side of the upper end terminal electrode had dye-sensitized TiO₂. The upper terminal (left) FTO glass was connected with a Pt plate to obtain hydrogen. The bipolar and Pt electrodes were inserted into a Pyrex glass tube and attached with a curable epoxy resin, with a spacing of about 0.1 cm. To prevent direct contact between cells and water electrolyte, all surfaces except the bottom Pt face were covered with a thin curable epoxy film.

FIG. 6c is a schematic of one embodiment of the a water photoelectrolysis cell 32 of the present invention. An epoxy layer 34 is applied to a first side of a bipolar FTO glass substrate 36. The second side of the bipolar FTO glass substrate 36 is separated from a dye sensitized TiO₂ layer 18 by an electrolyte 38 (e.g., MeCN+I₂+LiI+t-butylpyridine). The dye sensitized TiO₂ layer 18 in contact with a Pt film 22 which is in contact with another first side of a bipolar FTO glass substrate 36. The second side of the bipolar FTO glass substrate 36 is in contact with another layer of epoxy 34. The bipolar FTO glass substrate 36 extends to form a second electrode. The second side of the bipolar FTO glass substrate 36 is separated from a dye sensitized TiO₂ layer 18 by an electrolyte 38 (e.g., MeCN+I₂+LiI+t-butylpyridine). The dye sensitized TiO₂ layer 18 in contact with a Pt film 22 which is in contact with another first side of a bipolar FTO glass substrate 36. The second side of the bipolar FTO glass substrate 36 is in contact with another layer of epoxy 34. The bipolar FTO glass substrate 36 extends to form a third electrode. The second side of the bipolar FTO glass substrate 36 is separated from a dye sensitized TiO₂ layer 18 by an electrolyte 38 (e.g., MeCN+I₂+LiI+t-butylpyridine). The dye sensitized TiO₂ layer 18 in contact with a Pt film 22 which is in contact with another first side of a bipolar FTO glass substrate 36. Glass substrate 40 and silver paste 42 are used to seal the chamber. The second side of the bipolar FTO glass substrate 36 is in contact with another Pt film 22.

Light source: Illumination for the photoelectrolysis was produced by about a 2500 W xenon lamp from which infrared wavelengths were removed by about an 8-in water filter. The measured light irradiance was about 100 mW/cm².

For unassisted water splitting, the internally connected photovoltaic cell must provide sufficient voltage to drive the water redox reactions, i.e. the needed thermodynamic free energy (e.g., about 1.23 V at about 25° C.), plus additional voltage to overcome kinetic limitations and internal resistive losses.

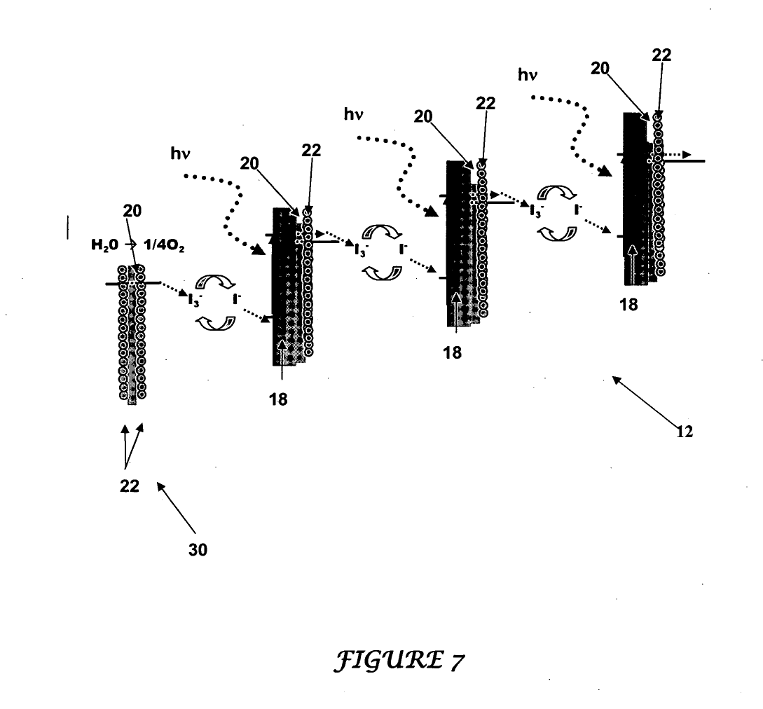

FIG. 7 shows an idealized energy-level diagram for water splitting with this bipolar photoelectrode array process, which includes three photons to drive one separated electron-hole pair. When light irradiates the three photoelectrodes, the absorbed photons produce three electron-hole pairs and essentially the same photovoltage, V₁, at each. In these cells, the electrons and holes cause the oxidation of I³⁻ and the reduction of I³⁻ in the MeCN. H₂ and O₂ evolution at the Pt deposited Ti foil will occur when the resultant photovoltage V=3V₁ is greater than that required for water decomposition for this particular cell structure. Three photons are required to produce one electron in the external circuit, so six photons are required to produce one molecule of H₂.

FIG. 7 illustrates the energy level diagram for the photoelectrochemical water splitting device, where the energetics of vectorial electron transfer from one bipolar photoelectrode to the other. The scheme consists of two photons required to produce one separated electron-hole pair. Since the photocurrent of tandem cells is limited by the lowest-current cell, current-matching in the component cells is critical for good performance. FIG. 7 is a schematic of the energy level diagram having three TiO₂/Pt electrodes 12 and a Pt electrode 30 separated by an iodide/iodine couple in MeCN for the internal bridge not shown. The TiO₂/Pt electrodes 12 have a dye sensitized TiO₂ layer 18 in contact with a Ti foil layer 20, which is in contact with a Pt film 22. The reaction at the TiO₂/Pt electrodes 12 is H₂O→½H₂ while the reaction at the Pt electrode 14 is H₂O→¼O₂.

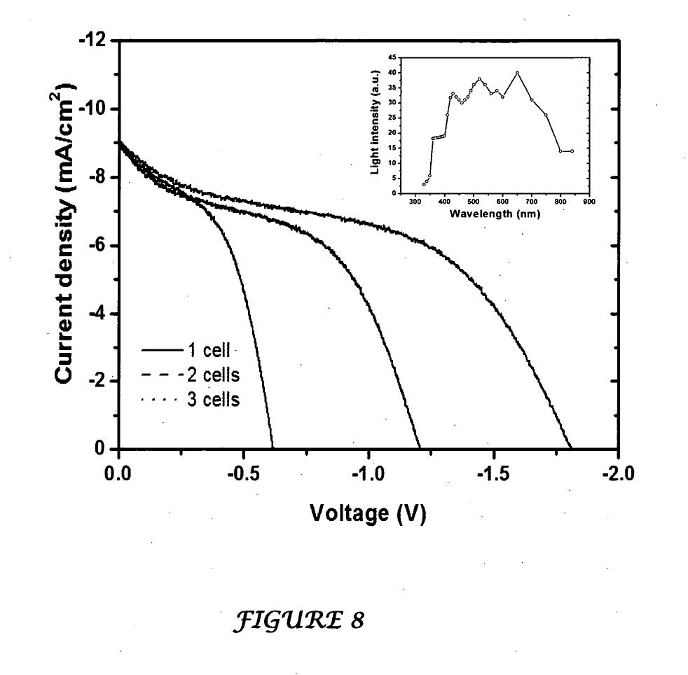

The power characteristics of a three photoelectrode array (structure A) and the spectral distribution of the xenon lamp are shown in FIG. 8. Because the multilayer semiconductor electrode structures involving several photoactive junctions are connected in series, the open circuit photovoltages were additive, yielding about 1.8 V. The fill factor, FF, for the series three-cell array was about 0.48. This is smaller than that in the usual DSSC, because the 1cm distance between each panel produced a relatively high ionic resistance. The efficiency for electric power generation measured for the three photoelectrode panels was about 2.5% as calculated by
η=V_{oc}i_{sc}FF/PᵢₙN
where N is the number of photopanels. If a correction is made for the absorption of light by the electrolyte and the effect of the light incident angle (the light flux is directed 45° from the normal to the panels), the efficiency is higher. When the Pt faces contacted aq. KOH and were connected by a KOH salt bridge, as shown in FIG. 6, bubble formation, presumed to be hydrogen and oxygen, was observed.

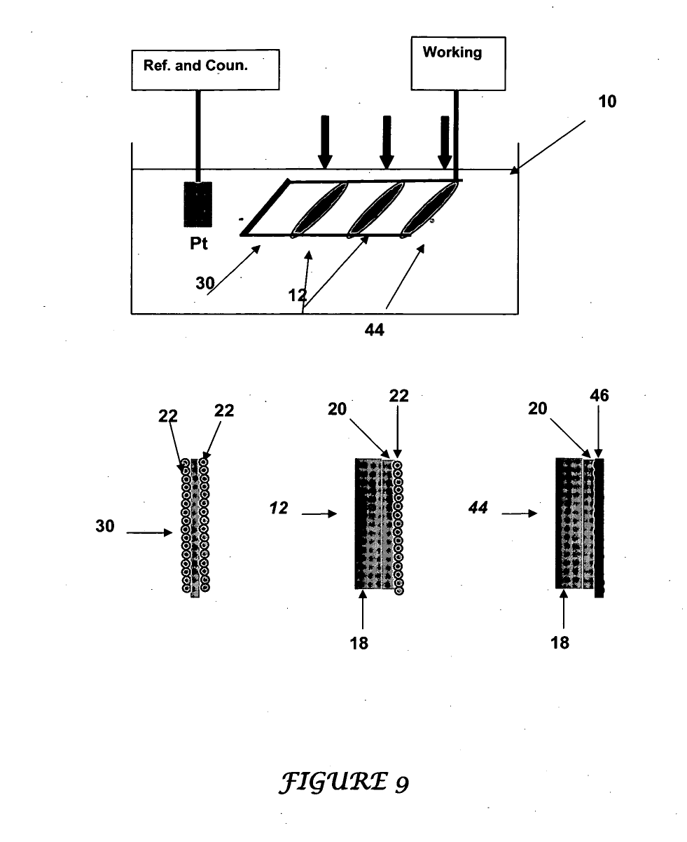

FIG. 9 is a schematic of another water photoelectrolysis cell 10, where the expansion shows concrete structure and energetics of bipolar panel. The water splitting cell using bipolar Pt and dye-sensitized TiO₂/Pt electrodes capable of vectorial electron transfer using two bipolar electrodes connected by the iodide/iodine couple in MeCN for the internal connections (e.g., MeCN+I₂+LiI+t-butylpyridine) and can permit unassisted photolytic water splitting. The device of the present invention is different than previously reported tandem cells in the art (e.g., the Grätzel group) in that the external wiring between the photoelectrochemical cells has been replaced by internal vectorial electron transfer resulting in a monolithic water splitting device. FIG. 9 is a schematic of a water photoelectrolysis cell 10 having three TiO₂/Pt electrodes 12, 12 and 44 and a Pt electrode 30 separated by an iodide/iodine couple in MeCN. Each of the TiO₂/Pt electrodes 12 have a dye sensitized TiO₂ layer 18 in contact with a Ti foil layer 20, which is in contact with a Pt film 22. The Pt electrode 14 includes a Ti foil layer 20, which is in contact with a Pt film 22. The TiO₂/Pt electrodes 44 has a dye sensitized TiO₂ layer 18 in contact with a Ti foil layer 20, which is in contact with an insolating layer 46. The Pt electrode 14 includes a Ti foil layer 20, which is in contact with a Pt film 22.

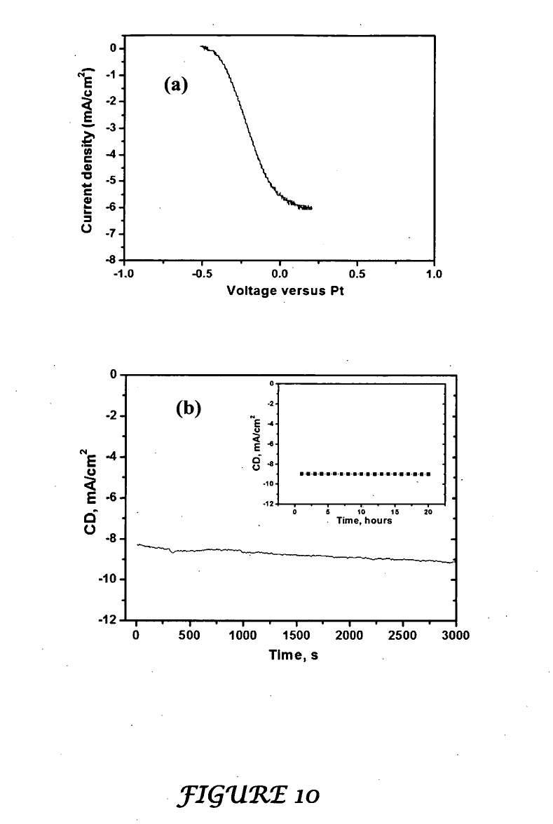

FIGS. 10a and 10b are graphs that shows the solar to chemical conversion efficiency of the bipolar semiconductor photoelectrochemical (PEC) array. FIG. 10a is a graph of the current density-voltage characteristics for photoelectrode PEC array connected by a 2 M KOH bridge under white light illumination. The PEC array was also evaluated by measuring the photocurrent density in the cell, in which the back of the Ti film in bipolar electrode 44 was insulated with epoxy cement and this Ti connected externally through a potentiostat to a Pt gauze electrode. FIG. 10a shows a graph of the photocurrent-voltage curves for this two-electrode configuration. Under illumination at open circuit, the Pt gauze electrode showed a potential of about −400 mV with respect to electrode 44 in the array, indicating that no additional external voltage was needed for hydrogen generation. At short circuit, the photocurrent density reached 5.4 mA/cm². The chemical efficiency during H₂ production was calculated by the following equation: efficiency=(power out)/(power in). The input power is the incident light intensity of about 100 mW/cm². For the output power, assuming 100% photocurrent electrolysis efficiency, the H₂ production photocurrent of about 5.4 mA/cm² is multiplied by about 1.23 V, which is the standard electrode potential at about 25° C. From this equation, the H₂ production efficiency of our system is about 2.2%. The value is significant in that this efficiency is realized by a photovoltaic cell with only about 2.5% solar-to-electrical conversion efficiency. The solar-to-hydrogen efficiency of the photoelectrode PEC array at zero bias was about 88% of the solar-to-electrical conversion efficiency of the inner photovoltaic cell. This means that the maximum operating voltage of the photoelectrode PEC array is very close to that required for electrolysis.

The Pt surfaces of the photoelectrode PEC array are exposed to the aqueous electrolyte, excellent corrosion resistance is expected. In addition, the stability of DSSCs have been improved dramatically, with stable performance under both thermal stress and light soaking matching the durability criteria applied to silicon solar cells for outdoor applications. The internal DSSCs in our system did not show leakage of the MeCN electrolyte into the surrounding aqueous solution and did not need any external leads or internal separators. This suggests that the stability of internally connected photoelectrode PEC array should be very high. FIG. 10b is a graph of the photocurrent vs. time profile for this array under short circuit conditions. The current density increased slightly for about 3000 s but then stabilized at about 9 mA/cm². The inset in FIG. 10B shows the long-term current stability of the internal connection of the photoelectrode PEC array. After 20 h, the initial current density of 9 mA/cm² remained constant, supporting the above hypothesis.

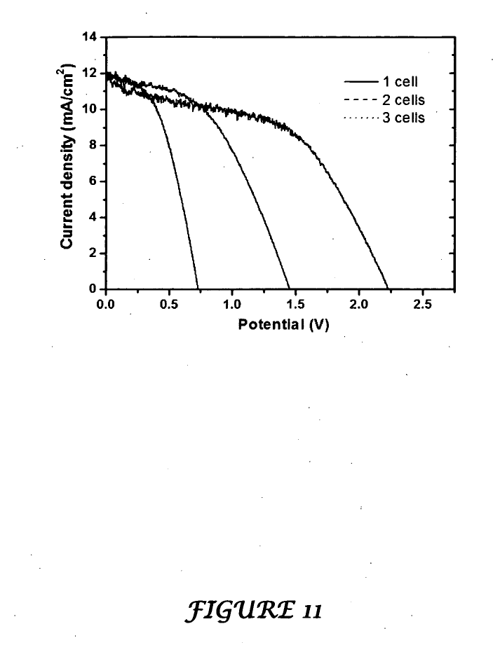

The power characteristics of a three photoelectrode array are shown in FIG. 11. The open circuit photovoltages were also additive, yielding about 2.1 V. The fill factor, FF, for the series three-cell array was about 0.52. The efficiency for electric power generation measured for the 3 photoelectrode panels was 4.5%.

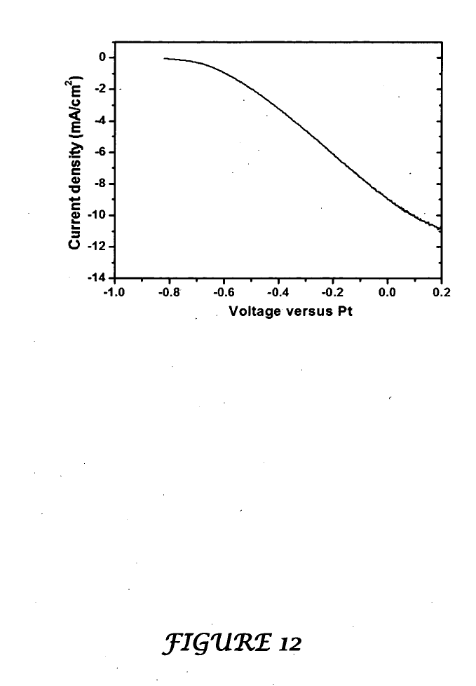

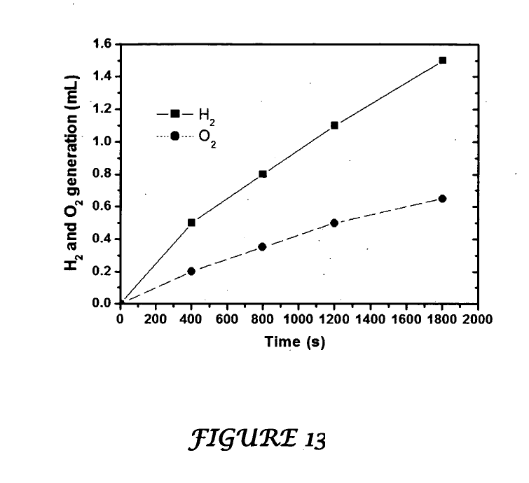

FIG. 12 is a graph of the photocurrent-voltage curves for this two-electrode configuration in a water electrolyte. The H₂ production photocurrent and efficiency was about 8.9 mA/cm² and about 3.7%, respectively. At zero bias (short circuit), copious gas bubbles were seen evolving from both the surface of the bottom terminal electrode and counter Pt plate. The evolved gases were collected during about 30 min. FIG. 13 is a schematic that show the production of hydrogen and oxygen occurs with a H₂:O₂ ratio of about 2.2:1.

The present invention provides the splitting of water into H₂ and O₂ using the bipolar Pt/dye-sensitized TiO₂ photoelectrode panels, capable of vectorial electron transfer, with light as the only energy input. The maximum photocurrent density of the PEC arrays operating at zero bias and a light intensity of about 100 mW/cm² was about 8.9 mA/cm² corresponding to about a 3.7% light-to-hydrogen conversion efficiency. In these photoelectrode PEC array, three photons are required to produce one electron in the external circuit, so six photons are required to produce one molecule of H₂. This is a similar to a D4 scheme in III/V semiconductor tandem cells. However, great care needs to be taken in the III/V semiconductor tandem cells to match the photon absorption characteristics so that equal numbers of photocarriers are generated in the top and bottom cells. Although solar-to-hydrogen efficiency of the PEC array is low compared with that of III/V semiconductor tandem cells, the low cost of the cell materials and possible enhancements in the DSSC efficiencies, make this arrangement an interesting one for further development.

The present invention provides a tandem photoelectrochemical cell with vectorial electron transfer for water splitting, which leads to an unassisted and monolithic system. Water can be split into hydrogen and oxygen using the WO₃/DSSC/Pt device, with light as the only energy input. The new electrophoretically deposited WO₃ films on Ti foil show a high photocurrent compared to other WO₃ preparations resulting in a 2.5% maximum solar-to-hydrogen conversion efficiency (under 0.15 V externally applied bias).

The present invention includes a monolithic photoelectrochemical cell for photoelectrical-induction of a chemical reaction capable of vectorial electron transfer. The monolithic photoelectrochemical cell includes a semiconductor electrode and a dye sensitized electrode positioned in communication with an electrolyte whereby the electrode is capable of capable of vectorial electron transfer upon exposure to electromagnetic radiation.

More particularly, the present invention includes a monolithic photoelectrochemical cell for photoelectrical-induction of a chemical reaction capable of vectorial electron transfer including a WO₃ semiconductor electrode and a Ruthenium sensitized TiO₂ electrode positioned in communication with an iodide/iodine electrolyte whereby the electrode is capable of vectorial electron transfer upon exposure to electromagnetic radiation.

The present invention also includes an inducible photoelectrochemical cell for photoelectrical-induction of a chemical reaction. The cell includes a housing having a first end and a second end connected by one or more walls with a semiconductor electrode and a dye sensitized electrode positioned within the housing. The semiconductor electrode and the dye sensitized electrode are in communication through an electrolyte.

The semiconductor electrode is coated with a metal oxide, e.g., WO₃/Pt. The semiconductor electrode includes a Ti substrate coated with a metal oxide, in some instances the metal oxide is WO₃. The semiconductor electrode includes metallically conductive substances, e.g. Au, Ag, Pt, Cu, W or other metals. In other instances, the semiconductor electrode includes a ceramic metal oxide (e.g., tin dioxide (SnO₂), tungsten trioxide (WO₃), ferric oxide (Fe₂O₃), and aluminium oxide (Al₂O₃)), with platinum (Pt) and palladium (Pd). In addition the semiconductor electrode may include MgO, MgAl₂O₄, MgTiO₃, Mg₂SiO₄, CaSiO₃, MgSrZrTiO₆, CaTiO₃, Al₂O₃, SiO₂, BaSiO₃, SrSiO₃, MgAl₂O₄, WO₃, SnTiO₄, ZrTiO₄, CaSnO₃, CaWO₄, CaZrO₃, MgTa₂O₆, MgZrO₃, MnO₂, PhO, Bi₂O₃, Si₃N₄, SnO₂, ZnO, ZrO₂ and/or La₂O₃. Additionally, for some applications it is also possible to use translucent conductive substances such as doped metal oxides, e.g. indium-tin oxide, Sb-doped tin oxide or Al-doped zinc oxide. For example, the semiconductor electrode may be prepared by deposition of a metal oxide (e.g., WO₃) on a metal (e.g., mechanically polished Ti substrate) by electrophoresis (e.g., about −430 mV vs. Ag/AgCl, Pt mesh counter). The thickness of metal oxide (e.g., WO₃) was controlled by consecutive electrodepositions, each followed by a heat treatment. Additionally, the materials may be deposited by sputtering, a sol-gel technique, by a pyrolysis technique of CVD or plasma CVD, by sputtering, or by corona discharge.

Additional minor additives or dopants in amounts of from about 0.1 to about 5 weight percent can be added to the materials to additionally improve the electronic properties. These minor additives include oxides such as zirconnates, stannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆, SnO₂, ITO and Ta₂O₃.

The dye sensitized electrode includes a dye sensitized metal oxide. The metal oxide electrode includes a dye sensitized metal oxide layer in contact with a metal foil layer in contact with a metal film. The dye sensitized electrode electrode includes metallically conductive substances, e.g. Au, Ag, Pt, Cu, Ti or other metals. For example, the TiO₂/Pt electrode has a dye sensitized TiO₂ layer in contact with a Ti foil layer in contact with a Pt film. In the preparation of the dye sensitized electrode a platinum film was deposited onto one side of about Ti foil by sputtering. Additionally, the materials may be deposited by sputtering, a sol-gel technique, by a pyrolysis technique of CVD or plasma CVD, by sputtering, or by corona discharge. Additionally, for some applications it is also possible to use transparent conductive substances such as doped metal oxides, e.g. indium-tin oxide, Sb-doped tin oxide or Al-doped zinc oxide. A film of TiO₂ nanoparticles was printed on another Ti foil. After sintering, the TiO₂ coated Ti foil was dye-coated by immersing it in about solution of dye solution.

Additional minor additives in amounts of from about 0.1 to about 5 weight percent can be added to the materials of the dye sensitized electrode to additionally improve the electronic properties. These minor additives include oxides such as zirconnates, stannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆ and Ta₂O₃.

Suitable semiconductors for the electrodes are thus preferably metal oxide semiconductors, in particular the oxides of transition metals and of the elements of main group III and transition groups IV, V and VI of the Periodic Table of the Elements, of titanium, zirconium, hafnium, strontium, zinc, indium, yttrium, lanthanum, vanadium, niobium, tantalum, chromium, molybdenum, tungsten, but also oxides of zinc, iron, nickel or silver, perovskites such as SrTiO₃, CaTiO₃, or oxides of other metals of main groups II and III or mixed oxides or oxide mixtures of these metals. However, it is also possible to use any other metal oxide having semiconducting properties and a large energy difference (band gap) between valence band and conduction band. Titanium dioxide is particularly preferred as semiconductor material.

The semiconductor material includes semiconducting oxides of the transition elements, semiconducting oxides of the elements of columns 13 and 14 of the periodic classification and semiconducting lanthanide oxides, a second group consisting of mixed semiconducting oxides formed of a mixture of two or more oxides of the first group, a third group consisting of mixed semiconducting oxides formed of a mixture of one or more oxides of the first group with oxides of the elements of columns 1 and 2 of the modem periodic classification, and a fourth group consisting of silicon, silicon hydride, silicon carbide, germanium, cadmium sulphide, cadmium telluride, zinc sulphide, lead sulphide, iron sulphide, zinc selenide, gallium arsenide, indium phosphide, gallium phosphide, cadmium phosphide, titanium fluoride, titanium nitride, zirconium fluoride, zirconium nitride, doped diamond, copper thiocyanate, and pure and mixed chalcopyrites.

In addition, sintering additives may be added to the electrode material, e.g., material selected from the group consisting of SiO₂, alkaline earth metal oxides, oxides from group III B and IV B of the periodic system, rare earth oxides of at least one of V, Nb, Ta, Cr, Fe, Co Ni oxide, B₂O₃, Al₂O₃, TiO₂, and combinations thereof. In another example, the sintering additives includes at least one member selected from the group consisting of carbides, nitrides, carbonitrides, oxynitrides, silicides and borides of at least one element selected from the group consisting of Si, Al, T, Zr, Hf, V, Nb,. Ta, Cr, Mo, W, Mn, Fe, Ca and Ni.

The dye sensitized electrode includes various chromophores or photosensitizing agents have different spectral sensitivities, e.g., Ruthenium compounds. The electrode is coated with a dye solution. Suitable photosensitizing agents may include, for example, dyes that include functional groups, such as carboxyl and/or hydroxyl groups, that can bond or chelate to the nanoparticles, e.g., to Ti(IV) sites on a TiO₂ surface. In one example, the electrode is coated with a Ru-dye in an acetonitrile and t-butanol solution. The choice of chromophore can thus be matched to the spectral composition of the light of the light source in order to increase the yield as much as possible. Suitable chromophores, i.e. sensitizers, are, in particular, the complexes of transition metals of the type metal(L3), metal(L2) of ruthenium and osmium (e.g. ruthenium-tris(2,2′-bipyridyl-4,4′-dicarboxylic acid)) and their salts, ruthenium cis diaqua bipyridyl complexes such as ruthenium cis-diaqua-bis(2,2′-bipyridyl-4,4′dicarboxylates) and also porphyrins (e.g. zinc tetra(4-carboxyphenyl)porphyrin) and cyanides (e.g. iron hexacyanide complexes) and phthalocyanines. Examples of suitable dyes include, but are not limited to, anthocyanins, porphyrins, phthalocyanines, merocyanines, cyanines, squarates, eosins, and metal-containing dyes such as, for example, cis-bis(isothiocyanato)bis(2,2′-bipyridyl-4,4′-dicarboxylato)-ruthenium(II)(“N3 dye”); tris(isothiocyanato)-ruthenium(II)-2,2′:6′,2″-terpyridine-4,4′,4″-tricarboxylic acid; cis-bis(isothiocyanato)bis(2,2′-bipyridyl-4,4′-dicarboxylato)-ruthenium(II)bis-tetrabutylammonium; cis-bis(isocyanato)(2,2′-bipyridyl-4,4′ dicarboxylato)ruthenium(II); and tris(2,2′-bipyridyl-4,4′-dicarboxylato)ruthenium(II) dichloride, all of which are available from Solaronix. In addition the dye may be a single molecule, a semiconductor crystal network, or an organic polymer.

The dye sensitized electrode and the semiconductor electrode are positioned into a housing and attached at an angle, with a spacing to allow irradiation of the photoactive sides of the electrodes. The present invention includes an electrolyte in the form of a solid, a gel or a liquid. The electrolyte composition is adapted for use in a solar cell and fills the housing to connect electrolytically the internal faces of the two electrodes. For example in one embodiment, the electrolyte includes one or more iodide ions and one or more iodine ions. Generally, the electrolyte solution includes a compound of the formula MᵢXⱼ. The i and j variables are lor greater. X is a suitable monovalent or polyvalent anion such as a halide, perchlorate, thiocyanate, trifluoromethyl sulfonate, hexafluorophosphate, sulfate, carbonate, or phosphate, and M is a monovalent or polyvalent metal cation such as Li, Cu, Ba, Zn, Ni, lanthanides, Co, Ca, Al, Mg, or other suitable metals. For example, an iodide/iodine-containing electrolyte (e.g., 0.005 M I₂+0.5 M LiI+0.58 M t-butylpyridine in MeCN) is used. In one example, the electrolyte composition includes a mixture including about 90 wt % of an ionic liquid including an imidazolium iodide, from 0 to 10 wt % water, iodine at a concentration of at least 0.05 M, and methyl-benzimidazole. The imidazoliumiodide-based ionic liquid-is selected from butylmethylimidazolium iodide, propylmethylimidazolium iodide, hexylmethylimidazolium iodide, or combinations thereof and the like. The electrolyte composition may include LiCl. In various embodiments, the amount of LiCl ranges from about 1 wt % LiCl and 6 wt % LiCl, is at least about 1 wt % LiCl, or is less than about 6 wt % LiCl. In another embodiment, the electrolyte composition includes LiI. In various embodiments, the amount of LiI ranges from about 1 wt % LiI and 6 wt % LiI, is at least about 1 wt. % LiI, or is less than about 6 wt % LiI.

In some embodiments, the electrode metal foil is titanium and constructed using photosensitized nanoparticle material includes sinitered titania, the conductive layer is ITO. The manufacturing process includes (1) coating a titania dispersion continuously, intermittently, or in a patterned format (e.g., to discrete portions) on the metal foil; (2) in line high or low temperature sintering of the titania coated metal foil; (3) in line sensitization of the titania coating; (4) slitting (e.g., by an ultrasonic slitting technique described in more detail below) the metal foil into strips; (5) separating the strips, or ribbons, to a finite spacing by using a sequentially positioned series of guide roller or by simply conveying the slit strips over a contoured roll that provides lateral spreading and separation of the strips at a finite distance; and (6) laminating the strips to a first flexible, substrate. An electrolyte, counter electrode, and second substrate including a conductive layer may be laminated to the metal-foil-coated first substrate to complete the photovoltaic cell or module.

More particularly, the present invention includes a method of making an inducible photoelectrochemical cell by fbrming one or more semiconductor electrodes, forming one or more dye sensitized electrodes positioned and the connecting of the one or more semiconductor electrodes and the one or more dye sensitized electrodes with an electrolyte.

The present invention also includes a method of using electrical energy using an inducible photoelectrochemical cell by forming one or more semiconductor electrodes, forming one or more dye sensitized electrodes positioned and the connecting of the one or more semiconductor electrodes and the one or more dye sensitized electrodes with an electrolyte. The method provides for the exciting the one or more semiconductor electrodes, the one or more dye sensitized electrodes or combination thereof. Additionally, the present invention includes a housing having a first end and a second end connected by one or more walls with one or more semiconductor electrodes and one or more dye sensitized electrodes positioned within the housing.

For example, the present invention includes a method of making a monolithic photoelectrochemical cell by forming one or more semiconductor electrodes, forming one or more dye sensitized electrodes positioned and the connecting of the one or more semiconductor electrodes and the one or more dye sensitized electrodes with an electrolyte.

The present invention also includes a method of producing solar energy using a monolithic photoelectrochemical cell by forming one or more semiconductor electrodes, forming one or more dye sensitized electrodes and the connecting of the one or more semiconductor electrodes and the one or more dye sensitized electrodes with an electrolyte. The method provides for the exciting the one or more semiconductor electrodes, the one or more dye sensitized electrodes or combination thereof. Additionally, the present invention includes a housing having a first end and a second end connected by one or more walls with a semiconductor electrode and a dye sensitized electrode positioned within the housing.

More particularly, the dye sensitized electrode includes a foil substrate layer in contact with a dye sensitized metal oxide layer and a metal film. In one specific example, the dye sensitized TiO₂/Pt electrode includes a dye sensitized TiO₂ layer in contact with a Ti foil layer, which is in contact with a Pt film. The dye sensitized electrode includes a metal film deposited onto a first metal foil and a second metal foil. A nanoparticle layer is applied to a second metal film. The first metal foil and the second metal foil are sintering and coated with a dye layer. Specifically, the dye sensitized electrode includes a Pt film deposited onto a first Ti foil and a second Ti foil. The first Ti foil and the second Ti foil are sintered and coated with a Ru-dye layer.

For example, the semiconductor electrode includes a metal oxide in contact with a metal foil layer and a metal film. In one specific example, the semiconductor electrode includes a metal oxide includes WO₃, the metal foil layer includes Ti and the metal film comprises Pt. The metal oxide may be applied in a variety of manners including the coating onto a metal substrate.

The semiconductor electrode is coated with a metal oxide, e.g., WO₃/Pt. The semiconductor electrode includes a Ti substrate coated with a metal oxide, in some instances the metal oxide is WO₃. The semiconductor electrode includes metallically conductive substances, e.g. Au, Ag, Pt, Cu, W or other metals. In other instances, the semiconductor electrode includes a ceramic metal oxide (e.g., tin dioxide (SnO₂), tungsten trioxide (WO3), ferric oxide (Fe₂O₃), and aluminium oxide (Al₂O₃)), with platinum (Pt) and palladium (Pd). In addition the semiconductor electrode may include MgO, MgAl₂O₄, MgTiO₃, Mg₂SiO₄, CaSiO₃, MgSrZrTiO₆, CaTiO₃, Al₂O₃, SiO₂, BaSiO₃, SrSiO₃, MgAl₂O₄, WO₃, SnTiO₄, ZrTiO₄, CaSnO₃, CaWO₄, CaZrO₃, MgTa₂O₆, MgZrO₃, MnO₂, PhO, Bi₂O₃, Si₃N₄, SnO₂, ZnO, ZrO₂ and/or La₂O₃. Additionally, for some applications it is also possible to use translucent conductive substances such as doped metal oxides, e.g. indium-tin oxide, Sb-doped tin oxide or Al-doped zinc oxide. For example, the semiconductor electrode may be prepared by deposition of a metal oxide (e.g., WO₃) on a metal (e.g., mechanically polished Ti substrate) by electrophoresis (e.g., about −430 mV vs. Ag/AgCl, Pt mesh counter). The thickness of metal oxide (e.g., WO₃) was controlled by consecutive electrodepositions, each followed by a heat treatment. Additionally, the materials may be deposited by sputtering, a sol-gel technique, by a pyrolysis technique of CVD or plasma CVD, by sputtering, or by corona discharge.

Additional minor additives or dopants in amounts of from about 0.1 to about 5 weight percent can be added to the materials to additionally improve the electronic properties. These minor additives include oxides such as zirconnates, stannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆, ITO and Ta₂O₃.

The dye sensitized electrode includes a dye sensitized metal oxide. The metal oxide electrode includes a dye sensitized metal oxide layer in contact with a metal foil layer in contact with a metal film. The dye sensitized electrode electrode includes metallically conductive substances, e.g. Au, Ag, Pt, Cu, Ti or other metals. For example, the TiO₂/Pt electrode has a dye sensitized TiO₂ layer in contact with a Ti foil layer in contact with a Pt film. In the preparation of the dye sensitized electrode a platinum film was deposited onto one side of about Ti foil by sputtering. Additionally, the materials may be deposited by sputtering, a sol-gel technique, by a pyrolysis technique of CVD or plasma CVD, by sputtering, or by corona discharge. Additionally, for some applications it is also possible to use translucent conductive substances such as doped metal oxides, e.g. indium-tin oxide, Sb-doped tin oxide or Al-doped zinc oxide. A film of TiO₂ nanoparticles was printed on another Ti foil. After sintering, the TiO₂ coated Ti foil was dye-coated by immersing it in about solution of dye solution.

Additional minor additives in amounts of from about 0.1 to about 5 weight percent can be added to the materials of the dye sensitized electrode to additionally improve the electronic properties. These minor additives include oxides such as zirconnates, stannates, rare earths, niobates and tantalates. For example, the minor additives may include CaZrO₃, BaZrO₃, SrZrO₃, BaSnO₃, CaSnO₃, MgSnO₃, Bi₂O₃/2SnO₂, Nd₂O₃, Pr₇O₁₁, Yb₂O₃, Ho₂O₃, La₂O₃, MgNb₂O₆, SrNb₂O₆, BaNb₂O₆, MgTa₂O₆, BaTa₂O₆ and Ta₂O₃.

Suitable semiconductors for the electrodes are thus preferably metal oxide semiconductors, in particular the oxides of transition metals and of the elements of main group III and transition groups IV, V and VI of the Periodic Table of the Elements, of titanium, zirconium, hafnium, strontium, zinc, indium, yttrium, lanthanum, vanadium, niobium, tantalum, chromium, molybdenum, tungsten, but also oxides of zinc, iron, nickel or silver, perovskites such as SrTiO₃, CaTiO₃, or oxides of other metals of main groups II and III or mixed oxides or oxide mixtures of these metals. However, it is also possible to use any other metal oxide having semiconducting properties and a large energy difference (band gap) between valence band and conduction band. Titanium dioxide is particularly preferred as semiconductor material.

The semiconducter material includes semiconducting oxides of the transition elements, semiconducting oxides of the elements of columns 13 and 14 of the periodic classification and semiconducting lanthanide oxides, a second group consisting of mixed semiconducting oxides formed of a mixture of two or more oxides of the first group, a third group consisting of mixed semiconducting oxides formed of a mixture of one or more oxides of the first group with oxides of the elements of columns 1 and 2 of the modem periodic classification, and a fourth group consisting of silicon, silicon hydride, silicon carbide, germanium, cadmium sulphide, cadmium telluride, zinc sulphide, lead sulphide, iron sulphide, zinc selenide, gallium arsenide, indium phosphide, gallium phosphide, cadmium phosphide, titanium fluoride, titanium nitride, zirconium fluoride, zirconium nitride, doped diamond, copper thiocyanate, and pure and mixed chalcopyrites.

In addition sintering additives may be added to the electrode material, e.g., material selected from the group consisting of SiO₂, alkaline earth metal oxides, oxides from group III B and IV B of the periodic system, rare earth oxides of at least one of V, Nb, Ta, Cr, Fe, Co Ni oxide, B₂O₃, Al₂O₃, TiO₂, and combinations thereof. In another example, the sintering additives includes at least one member selected from the group consisting of carbides, nitrides, carbonitrides, oxynitrides, silicides and borides of at least one element selected from the group consisting of Si, Al, T, Zr, Hf, V, Nb, Ta, Cr, Mo, W, Mn, Fe, Ca and Ni.

The dye sensitized electrode includes various chromophores or photosensitizing agents have different spectral sensitivities, e.g., Ruthenium compounds. The electrode is coated with a dye solution. Suitable photosensitizing agents may include, for example, dyes that include functional groups, such as carboxyl and/or hydroxyl groups, that can chelate to the nanoparticles, e.g., to Ti(IV) sites on a TiO₂ surface. In one example, the electrode is coated with a Ru-dye in an acetonitrile and t-butanol solution. The choice of chromophore can thus be matched to the spectral composition of the light of the light source in order to increase the yield as much as possible. Suitable chromophores, i.e. sensitizers, are, in particular, the complexes of transition metals of the type metal(L3), metal(L2) of ruthenium and osmium (e.g. ruthenium-tris(2,2′-bipyridyl-4,4′-dicarboxylic acid)) and their salts, ruthenium cis diaqua bipyridyl complexes such as ruthenium cis-diaqua-bis(2,2′-bipyridyl-4,4-dicarboxylates) and also porphyrins (e.g. zinc tetra(4-carboxyphenyl)porphyrin) and cyanides (e.g. iron hexacyanide complexes) and phthalocyanines. Examples of suitable dyes include, but are not limited to, anthocyanins, porphyrins, phthalocyanines, merocyanines, cyanines, squarates, eosins, and metal-containing dyes such as, for example, cis-bis(isothiocyanato)bis(2,2′-bipyridyl-4,4′-dicarboxylato)-ruthenium(II)(“N3 dye”); tris(isothiocyanato)-ruthenium(II)-2,2′:6′,2″-terpyridine-4,4′4″-tricarboxylic acid; cis-bis(isothiocyanato)bis(2,2″-bipyridyl-4,4′-dicarboxylato)-ruthenium(II)bis-tetrabutylamrnonium; cis-bis(isocyanato)(2,2′-bipyridyl-4,4′ dicarboxylato)ruthenium(II); and tris(2,2′-bipyridyl-4,4′-dicarboxylato)ruthenium(II) dichloride, all of which are available from Solaronix.

The one or more dye sensitized electrodes and the one or more semiconductor electrodes are positioned into a housing and attached at an angle, with a spacing to allow irradiation of the photoactive sides of the electrodes. The present invention includes an electrolyte in the form of a solid, a gel or a liquid. The electrolyte composition is adapted for use in a solar cell and fills the housing to connect electrolytically the internal faces of the two electrodes. For example in one embodiment, the electrolyte includes one or more iodide ions and one or more iodine ions. Generally, the electrolyte solution includes a compound of the formula MᵢXⱼ. The i and j variables are 1 or greater. X is a suitable monovalent or polyvalent anion such as a halide, perchlorate, thiocyanate, trifluoromethyl sulfonate, hexafluorophosphate, sulfate, carbonate, or phosphase, and M is a monovalent or polyvalent metal cation such as Li, Cu, Ba, Zn, Ni, lanthanides, Co, Ca, Al, Mg, or other suitable metals. For example, an iodide/iodine-containing electrolyte (e.g., 0.005 M I₂+0.5 M LiI+0.58 M t-butylpyridine in MeCN) is used. In one example, the electrolyte composition includes a mixture including about 90 wt % of an ionic liquid including an imidazolium iodide, from 0 to 10 wt % water, iodine at a concentration of at least 0.05 M, and methyl-benzimidazole. The imidazoliumiodide-based ionic liquid is selected from butylmethylimidazolium iodide, propylmethylimidazolium iodide, hexylmethylimidazolium iodide, or combinations thereof and the like. The electrolyte composition may include LiCl. In various embodiments, the amount of LiCl is ranges from about 1 wt % LiCl and 6 wt % LiCl, is at least about 1 wt % LiCl, or is less than about 6 wt % LiCl. In another embodiment, the electrolyte composition includes LiI. In various embodiments, the amount of LiI ranges from about 1 wt % LiI and 6 wt % LiI, is at least about 1 wt % LiI, or is less than about 6 wt % LiI.

In some embodiments, the electrode is metal foil is titanium and constructed using photosensitized nanoparticle material includes sintered titania, the conductive layer is ITO. The manufacturing process includes: (1) coating a titania dispersion continuously, intermittently, or in a patterned format (e.g., to discrete portions) on the metal foil; (2) in line high or low temperature sintering of the titania coated metal foil; (3) in line sensitization of the titania coating; (4) slitting (e.g., by an ultrasonic slitting technique described in more detail below) the metal foil into strips; (5) separating the strips, or ribbons, to a finite spacing by using a sequentially positioned series of guide roller or by simply conveying the slit strips over a contoured roll that provides lateral spreading and separation of the strips at a finite distance; and (6) laminating the strips to a first flexible, substrate. An electrolyte, counter electrode, and second substrate including a conductive layer may be laminated to the metal-foil-coated first substrate to complete the photovoltaic cell or module.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations can be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

References:

i. G. R. Torres, T. Lindgren, J. Lu, C. G. Granqvist and S. E. Lindquist, J. Phys. Chem. B 108, 5995 (2004)
ii. A. J. Bard, M. A. Fox, Acc. Chem. Res. 28, 141 (1995)
iii. A. J. Bard, Science 207, 139 (1980)
iv. S. Licht, J. Phys. Chem. 105, 6281 (2001)
v. O. Khaselev, J. A. Turner, Science 280, 425 (1998)
vi. M. Grätzel, Nature 414, 338 (2001).
vii. A. Fujishima, K. Honda, Nature 238, 37 (1972)
viii. Y. Yamada, N. Matsuki, T. Ohmori, H. Kondo, A. Matsuda, E. Suzuki, Inter. J. Hydrogen Energy 28, 1167 (2003)
ix. E. L. Miller, B. Marsen, D. Paluselli, R. Rocheleau, Electrochem. Solid State Lett. 8(5), A247 (2005)
x. M. Grätzel, Cattech 3, 3 (1999)
xi. E. S. Smotkin, A. J. Bard, A. Campion, M. A. Fox, T. Mallouk, S. E. Webber, J. M. White, J. Phys. Chem. 90, 4604 (1986).
xii. E. S. Smotkin, S. C. March, A. J. Bard, A. Campion, M. A. Fox, T. Mallouk, S. E. Webber, J. M. White, J. Phys. Chem. 91, 6 (1987).
xiii. J. H. Park, A. J. Bard, Electrochem. Solid St. Letters, submitted
xiv. P. K. Shen, A. C. C. Tseung, J. Mater. Chem. 2, 1141 (1992)
xv. C. Santato, M. Ulmann, J. Augustynski, J. Phys. Chem. B 105, 936 (2001)
xvi. X. Gao, S. Kocha, A. J. Frank, J. A. Turner, Int. J. Hydro. Energy 24, 319 (1999)

What is claimed is:

1. A monolithic photoelectrochemical cell for photoelectrical-induction of a chemical reaction capable of vectorial electron transfer comprising:
one or more semiconductor electrodes and one or more dye sensitized electrodes positioned in communication with an electrolyte whereby the electrodes are capable of vectorial electron transfer upon exposure to electromagnetic radiation.

2. The apparatus of claim 1, wherein the one or more semiconductor electrodes comprise WO₃/Pt or TiO₂/Pt.

3. The apparatus of claim 1, wherein the one or more dye sensitized electrodes comprise Ruthenium.

4. The apparatus of claim 1, wherein the one or more electrolytes comprise one or more iodide ions, one or more iodine ions or a combination thereof.

5. The apparatus of claim 1, further comprising SiO₂, alkaline earth metal oxides, oxides from group III B, oxides from group IV B of the periodic system, rare earth oxides of at least one of V, Nb, Ta, Cr, Fe, Co Ni oxide, B₂O₃, Al₂O₃ or combinations thereof.

6. The apparatus of claim 1, further comprising one or more carbides, nitrides, carbonitrides, oxynitrides, silicides and borides of at least one element selected from the group consisting of Si, Al, T. Zr, Hf, V, Nb, Ta, Cr, Mo, W, Mn, Fe, Ca and Ni.

7. The apparatus of claim 1, wherein the one or more semiconductor electrodes comprise a metal oxide in contact with a metal foil layer and a metal film.

8. A monolithic photoelectrochemical cell for photoelectrical-induction of a chemical reaction capable of vectorial electron transfer comprising:
one or-more WO₃ semiconductor electrodes and one or more Ruthenium sensitized TiO₂ electrodes positioned in communication with an iodide/iodine electrolyte whereby the electrodes are capable of capable of vectorial electron transfer upon exposure to electromagnetic radiation.

9. An inducible photoelectrochemical cell for photoelectrical-induction of a chemical reaction comprising:
a housing comprising first end and a second end connected by one or more walls;
one or more semiconductor electrodes positioned within the housing;
one or more dye sensitized electrodes positioned within the housing; and
an electrolyte in communication with the one or more semiconductor electrodes and the one or more dye sensitized electrodes.

10. The apparatus of claim 9, wherein the one or more semiconductor electrodes comprise WO₃/Pt or TiO₂/Pt.

11. The apparatus of claim 9, wherein the one or more dye sensitized electrodes comprise Ruthenium.

12. The apparatus of claim 9, wherein the one or more electrolytes comprise one or more iodide ions, one or more iodine ions or a combination thereof.

13. A method of making an inducible photoelectrochemical cell comprising the steps of:
forming one or more semiconductor electrodes;
forming one or more dye sensitized electrodes; and
connecting the one or more semiconductor electrodes and the one or more dye sensitized electrodes with an electrolyte.

14. The method of claim 13, wherein the one or more semiconductor electrodes comprise a metal oxide in contact with a metal foil layer and a metal film.

15. The method of claim 13, wherein the one or more semiconductor electrodes comprise a metal oxide comprises WO₃, the metal foil layer comprises Ti and the metal film comprises Pt.

16. The method of claim 13, wherein the one or more semiconductor electrodes comprise a metal oxide layer coated onto a metal substrate.

17. The method of claim 13, wherein the one or more semiconductor electrodes comprise a WO₃ film coated on a Ti substrate.

18. The method of claim 13, wherein the one or more semiconductor electrodes comprise the metal film.

19. The method of claim 13, wherein the dye sensitized electrode comprises a foil substrate layer in contact with a dye sensitized metal oxide layer and a metal film.

20. The method of claim 19, wherein the foil substrate layer comprises Ti, the dye sensitized metal oxide layer comprises TiO₂ and the metal film comprises Pt.

21. The method of claim 13, wherein the one or more dye sensitized electrodes comprise a dye sensitized metal oxide layer applied by printing.

22. The method of claim 13, wherein the one or more dye sensitized electrodes comprise a Pt film is deposited onto a first Ti foil, a TiO₂ nanoparticle layer is applied to a second Ti film, the first Ti foil and the second Ti foil are sintered and coated with a Ru dye layer.

23. The method of claim 13, wherein the one or more dye sensitized electrodes comprise a metal film deposited onto a first metal foil, a nanoparticle layer applied to a second metal film, the first metal foil and the second metal foil are sintered and coated with a dye layer.

24. The method of claim 23, wherein the nanoparticle layer is applied by printing.

25. The method of claim 13, wherein the one or more dye sensitized electrodes comprise a Pt film deposited onto a first Ti foil, a TiO₂ nanoparticle layer applied to a second Ti film, the first Ti foil and the second Ti foil are sintered and coated with a Ru dye layer.

26. A method of producing solar energy using a monolithic photoelectrochemical cell comprising the steps of:
forming one or more semiconductor electrodes;
forming one or more dye sensitized electrodes in communication with the one or more semiconductor electrodes; and
connecting the one or more semiconductor electrodes and the one or more dye sensitized electrodes with an electrolyte; and
exciting the one or more semiconductor electrodes, the one or more dye sensitized electrodes or combination thereof.
